(19) United States
(12) Patent Application Publication
(10) Pub. No.: US 2006/0278913 A1
(43) Pub. Date: Dec. 14, 2006

(54) Non-volatile memory cells without diffusion junctions

(75) Inventors: Andrei Mihnea, Boise, ID (US); Behnam Moradi, Boise, ID (US); Paul J. Rudeck, Boise, ID (US); Aritome Seiichi, Boise, ID (US); Di Li, Boise, ID (US)

Correspondence Address: LEFFERT JAY & POLGLAZE, P.A., P.O. BOX 581009, MINNEAPOLIS, MN, 55458-1009, US

(73) Assignee: Micron Technology, Inc.

(21) Appl. No.: 11/147,976

(22) Filed: Jun. 8, 2005

(51) Int. Cl. H01L 29/788; H01L 21/336; G11C 16/04

(52) U.S. Cl. 257/314; 438/257; 257/316; 257/321; 365/185.01

(57) ABSTRACT

A plurality of memory cell stacks are formed over a substrate. The substrate does not have diffusion regions between each memory cell stack to link the memory cells. The cells are formed close enough such that the memory cells are linked serially by the electric fields generated by each floating gate in the channel regions. In one embodiment, an n-layer is implanted at the top of the substrate to increase conductivity between cells. The select transistors can be linked to the serial string by diffusion regions or by interaction of the electric fields between the select transistor channel and the memory cell channel.

### TECHNICAL FIELD OF THE INVENTION

The present invention relates generally to memory devices and in particular the present invention relates to non-volatile memory devices.

### BACKGROUND OF THE INVENTION

Memory devices are typically provided as internal, semiconductor, integrated circuits in computers or other electronic devices. There are many different types of memory including random-access memory (RAM), read only memory (ROM), synchronous dynamic random access memory (SDRAM), dynamic random access memory (DRAM), and flash memory.

Flash memory devices have developed into a popular source of non-volatile memory for a wide range of electronic applications. Flash memory devices typically use a one-transistor memory cell that allows for high memory densities, high reliability, and low power consumption. Common uses for flash memory include personal computers, personal digital assistants (PDAs), digital cameras, and cellular telephones. Program code and system data such as a basic input/output system (BIOS) are typically stored in flash memory devices for use in personal computer systems.

As computers become smaller and their performance increases, the computer memories have also gone through a corresponding size reduction and performance increase. However, flash memory devices present a challenge in scalability due, at least in part, to the high programming voltages typically required. Additionally, due to required real estate for contacts and other memory circuitry, the density of a memory device is also limited.

For the reasons stated above, and for other reasons stated below which will become apparent to those skilled in the art upon reading and understanding the present specification, there is a need in the art for a more scalable, higher density non-volatile memory device.

### SUMMARY

The above-mentioned problems with scalable memory and other problems are addressed by the present invention and will be understood by reading and studying the following specification.

The embodiments of the present invention encompass a memory device fabricated on a substrate. A plurality of memory cell stacks are formed over the substrate. Each memory cell stack is coupled to adjacent memory cell stacks only through an electric field generated by each stack.

In one embodiment, the substrate is comprised of a p-type silicon in which an n-layer is implanted near the top. The memory cells are fabricated over the n-layer. The memory cell stacks can be comprised of a tunnel dielectric, a floating gate, a gate dielectric, and a control gate.

Further embodiments of the invention include methods and apparatus of varying scope.

### BRIEF DESCRIPTION OF THE DRAWINGS

FIG. 1 shows a cross-sectional view of a typical prior art flash memory device.

FIG. 2 shows a cross-sectional view of one embodiment of a floating gate memory device of the present invention.

FIG. 3 shows a simplified diagram of one embodiment of a NAND flash memory array architecture of the present invention.

FIG. 4 shows the results of computer simulations in accordance with the embodiment of FIG. 2.

FIG. 5 shows the results of computer simulations in accordance with the embodiment of FIG. 2.

FIG. 6 shows the results of computer simulations in accordance with the embodiment of FIG. 2.

FIG. 7 shows a block diagram of one embodiment of an electronic system of the present invention.

FIG. 8 shows an alternate embodiment of a cross-sectional view of one embodiment of the floating gate memory device of the present invention.

### DETAILED DESCRIPTION

In the following detailed description of the invention, reference is made to the accompanying drawings that form a part hereof and in which is shown, by way of illustration, specific embodiments in which the invention may be practiced. In the drawings, like numerals describe substantially similar components throughout the several views. These embodiments are described in sufficient detail to enable those skilled in the art to practice the invention. Other embodiments may be utilized and structural, logical, and electrical changes may be made without departing from the scope of the present invention. The following detailed description is, therefore, not to be taken in a limiting sense, and the scope of the present invention is defined only by the appended claims and equivalents thereof. The terms wafer or substrate used in the following description include any base semiconductor structure. Both are to be understood as including silicon-on-sapphire (SOS) technology, silicon-on-insulator (SOI) technology, thin film transistor (TFT) technology, doped and undoped semiconductors, epitaxial layers of a silicon supported by a base semiconductor structure, as well as other semiconductor structures well known to one skilled in the art. Furthermore, when reference is made to a wafer or substrate in the following description, previous process steps may have been utilized to form regions/junctions in the base semiconductor structure, and terms wafer or substrate include the underlying layers containing such regions/junctions.

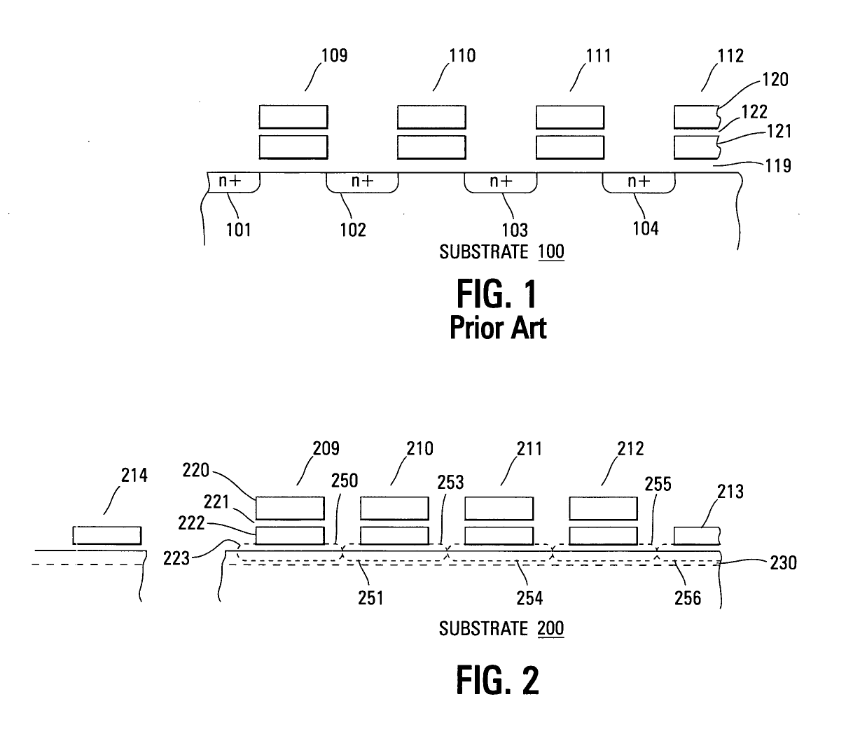

FIG. 1 illustrates a cross-sectional view of one embodiment of a typical prior art series string of NAND flash memory cells 109-112. A substrate 100, for example a p-type silicon, is implanted with n+ diffusion regions 101-104 that act as the transistor's 109-112 source and drain regions. The actual function of each region 109-112 depends on the direction of operation of the series string.

Each memory cell 109-112 is comprised of a floating gate 121 that stores the charge for the cell. The floating gate 121 is formed over a tunnel dielectric layer 119 and substantially between a pair of source/drain diffusion areas 101-104.

A gate dielectric layer 122 is formed over the floating gate 121 to isolate the control gate 120 from the floating gate 121. The floating gate 121 and the control gate 120 can be comprised of silicon material and the gate dielectric layer 122 is an interpoly dielectric.

FIG. 2 illustrates a cross-sectional view of one embodiment of a portion of the series string of the flash memory cells of the present invention without the diffusion areas. The memory cell stacks 209-212 of the present invention are coupled in series by the overlapping electric fields 250 generated in the substrate by each floating gate.

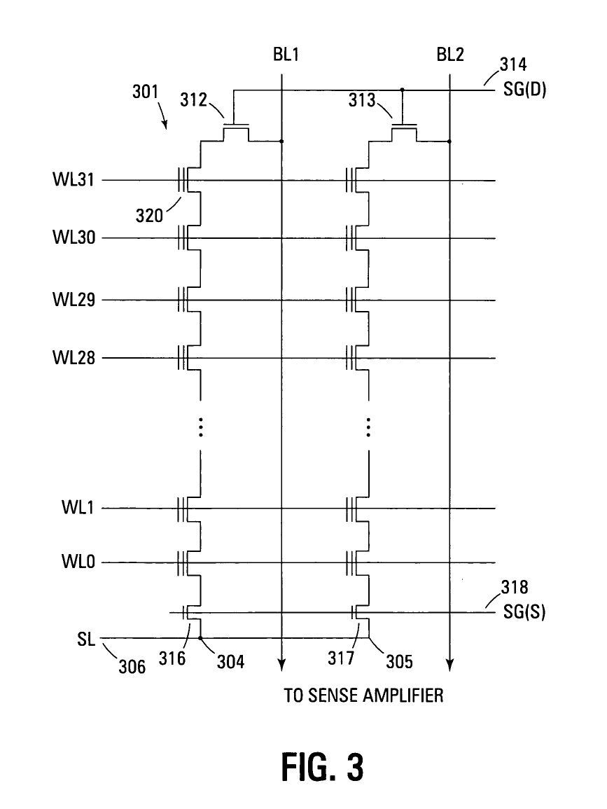

For purposes of clarity, not all of the elements of a memory column in a memory array are shown. In one embodiment, a series string of memory is comprised of 32 memory cells. However, alternate embodiments can use other quantities of memory cells such as 8 or 16. The series string of memory cells illustrated in FIG. 2 represents a partial memory column. A schematic illustrating the elements of a memory column of an array are discussed subsequently in greater detail with reference to FIG. 3.

The memory cells 209-212 are fabricated on a silicon substrate 200. In one embodiment, the substrate 200 is a p-type silicon. However, the present invention is not limited to any one conductivity substrate or material.

A tunnel dielectric layer 223 is formed over the substrate 200. This layer can be comprised of an oxide such as silicon dioxide (SiO₂) or another material such as a high dielectric constant (high-K) material. In one embodiment, a high dielectric constant is considered to be a dielectric constant that is greater than that of SiO₂. For example, LaAlO can be used as the high-k tunneling gate dielectric 223 instead of SiO₂. Alternate embodiments may use other dielectrics having other dielectric constants.

The floating gate layer 222 is formed over the tunnel dielectric layer 223. In one embodiment, this charge storage layer 222 is a polysilicon material and is thinner than the prior art floating gate. In one embodiment, the floating gate layer 222 is formed less than 2000 Å. Alternate embodiments use other thicknesses. In another embodiment, the charge storage layer 222 and the dielectric layers 223, 221 are formed as an oxide-nitride-oxide (ONO) film.

An intergate dielectric layer 221 is formed over the floating gate 222. The intergate layer 221 and the tunnel dielectric isolate the floating gate 222 from the control gate 220 and the substrate 200, respectively. The intergate dielectric layer 221 can be comprised of an oxide material or some other type of insulator. A polysilicon layer 220 is formed over the intergate dielectric layer 221 to act as the control gate 220 for each cell. In an alternate embodiment, the control gate 220 can be formed from a metal layer.

The above-described layers, in one embodiment, use a known hard mask and spacer etch process to form the individual memory cells 209-212 of the memory column. The distance between the memory cells 209-212 of the embodiments of the present invention is substantially reduced from the prior art. A typical distance between memory cells of the prior art is in a range of 50 to 180 nm, depending on minimum lithography size and etching methods used in fabrication. The lack of diffusion areas in the present invention allows the memory cell stacks to be formed closer together. In one embodiment, the stacks can be formed within a range of 5-90 nm apart. This permits the electric fields 250-255 generated by each floating gate to be coupled to an adjacent electric field 250-255. The reduced distance permits a greater number of memory cells to fit in each column, thus increasing the density of the flash memory device. The present invention, however, is not limited to any one distance or range of distances between memory cell stacks. Alternate embodiments may use other distances or ranges.

In one embodiment, an n-layer 230 is implanted on the surface of the substrate 200. This layer 230 is not required for proper operation of the memory cells. However, such a layer 230 increases the conductivity of the channels under each gate. Such a layer may be less than 0.1 μm from the top of the substrate.

Each end of each series string of memory cells 209-212 is coupled to a select transistor 213, 214 that controls access to the string of cells 209-212. One end has a select gate drain transistor 213 and the other end a select gate source transistor 214. Each transistor 213, 214 couples the respective end to the bit line or the source line.

In one embodiment, the right drain diffusion region and the left source diffusion region are not needed. The right memory cell 212 is formed close enough to the select gate drain transistor 213 so that the electric field of the floating gate interacts with the electric field of the select gate transistor 213. Similarly, the left memory cell is formed close enough to the select gate source transistor 214 such that the electric field of the floating gate interacts with the electric field of the select gate transistor 214. Such an embodiment enables the transistors to be formed even closer together.

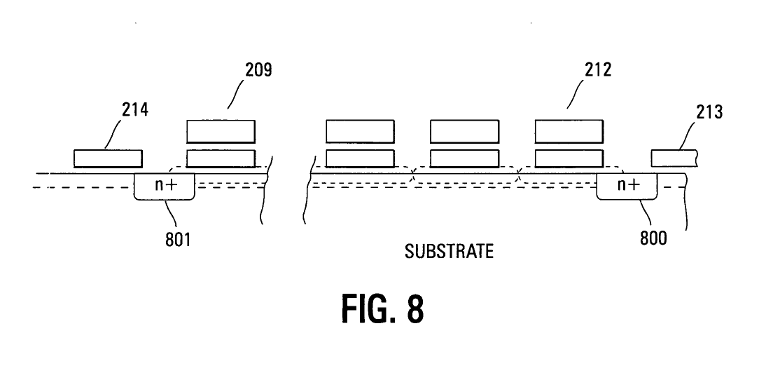

FIG. 8 illustrates an alternate embodiment in which the memory cell at the left and right of each string has an implanted diffusion region 800, 801 in order to couple to the select gate transistor 213, 214. For example, in order to couple the select gate drain transistor 213 to the right memory cell 212, a drain diffusion region 800 may be formed in the substrate between the two transistors 212, 213. This could be repeated at the other end of the string with the select gate source transistor 214 and the left memory cell 209.

The memory device of the present invention is programmed in a substantially similar way as prior art memory devices. This method includes a series of programming pulses on a selected word line and an inhibit voltage (e.g., V_{CC}) on the array bit lines that are not to be programmed. The bit lines with memory cells to be programmed are typically biased at ground potential. The series of programming voltages may start at an initial high voltage (e.g., 16V) and increment by predetermined voltages until either the cell or cells are programmed or an error condition exists.

However, since the embodiments of the present invention do not use diffusion regions, the physical mechanism of a program inhibit operation is different than the prior art mechanism. In a prior art NAND device, the program inhibit occurs when bit lines to be inhibited are biased at V_{CC} and the string inversion layer and diffusions experience channel bootstrap or coupling to a high voltage by the unselected word lines. In the present invention of the string of cells with no diffusion regions, the program inhibit is ensured by the formation of a deep depletion area in the substrate under the string of cells using substantially similar bias conditions. This leads to a suppression of electron tunneling by reduction of the tunnel oxide field due to an increased voltage drop in the channel region under the memory cell stack.

FIG. 3 illustrates a simplified diagram of one embodiment for a NAND flash memory array of the present invention. The memory array of FIG. 3, for purposes of clarity, does not show all of the elements typically required in a memory array. For example, only two bit lines are shown (BL1 and BL2) when the number of bit lines required actually depends upon the memory density. Additionally, each memory column extends vertically, substantially repeating the series strings of memory cells between two select gates.

The array is comprised of an array of floating gate cells 301 arranged in series strings 304, 305. Each of the floating gate cells 301 are coupled drain to source in each series chain 304, 305. A word line (WL0-WL31) that spans across multiple series strings 304, 305 is coupled to the control gates of every floating gate cell in a row in order to control their operation. The embodiment of FIG. 3 shows 32 word lines per subset of memory cells. Alternate embodiments could have different quantities of word lines such as 8, 16, or more.

In operation, the word lines (WL0-WL31) select the individual floating gate memory cells in the series chain 304, 305 to be written to or read from and operate the remaining floating gate memory cells in each series string 304, 305 in a pass through mode. Each series string 304, 305 of floating gate memory cells is coupled to a source line 306 by a source select gate 316, 317 and to an individual bit line (BL1-BLN) by a drain select gate 312, 313. The bit lines (BL1-BLN) are eventually coupled to sense amplifiers (not shown) that detect the state of each cell.

The source select gates 316, 317 are controlled by a source select gate control line SG(S) 318 coupled to their control gates. The drain select gates 312, 313 are controlled by a drain select gate control line SG(D) 314.

Each cell can be programmed as a single bit per cell (SBC) or multiple bits per cell (i.e., multilevel cell—MLC). Each cell's threshold voltage (Vₜ) determines the data that is stored in the cell. For example, in a single bit per cell, a Vₜ of 0.5V might indicate a programmed cell while a Vₜ of −0.5V might indicate an erased cell.

During a typical prior art programming operation, the selected word line for the flash memory cell to be programmed is biased with a programming pulse at a voltage that is greater than 16V. A verification operation with a word line voltage (e.g., 0.5V) is then performed to determine if the cell threshold voltage has been increased to the corresponding level of 0.5V in the program operation. The unselected word lines for the remaining cells are typically biased at approximately 10V during the program operation. Each of the memory cells is programmed in a substantially similar fashion.

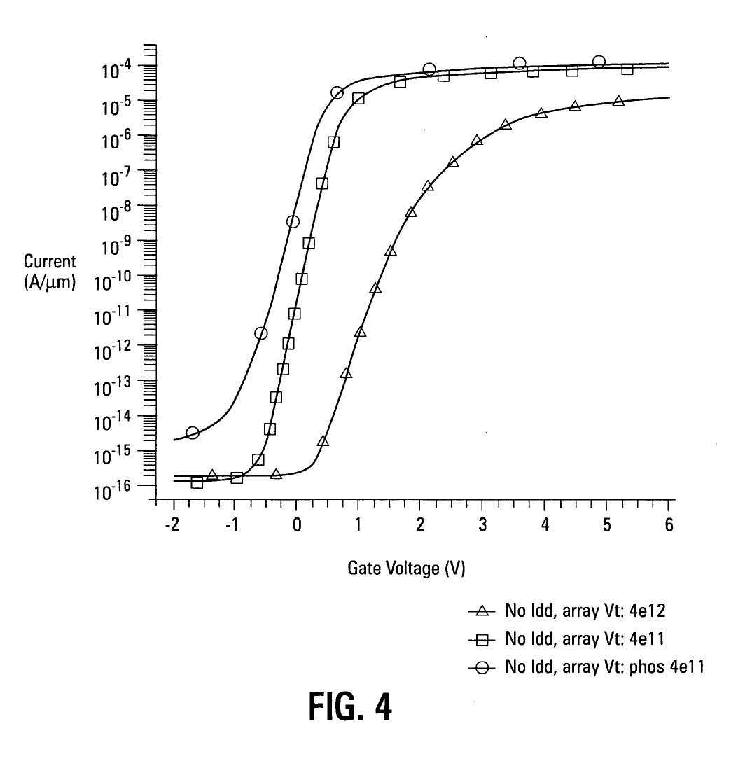

FIGS. 4-6 illustrate the results of computer simulations of embodiments of the non-volatile memory cells without diffusion junctions of the present invention. FIG. 4 illustrates the on-off characteristics with three different threshold voltage adjustment implant schemes.

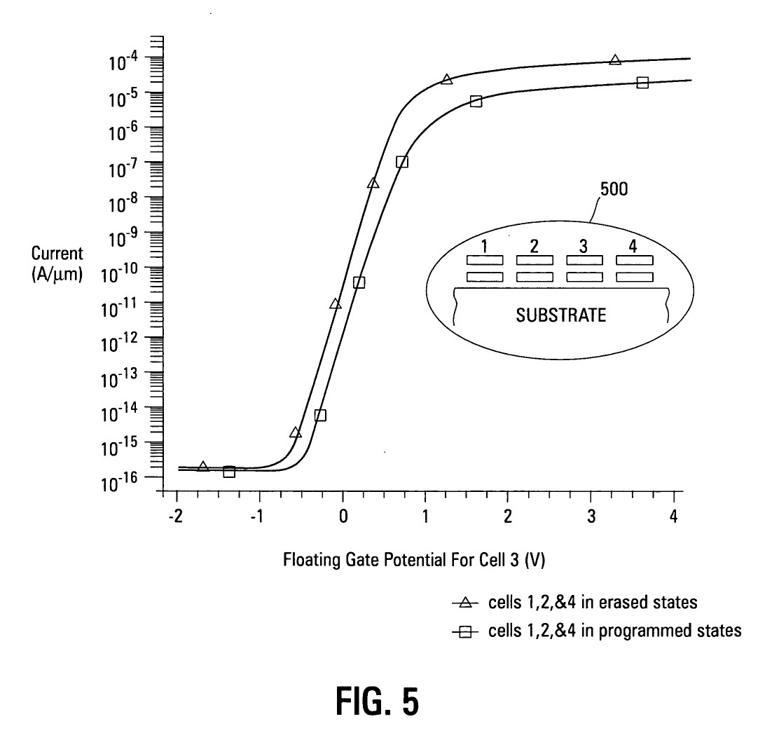

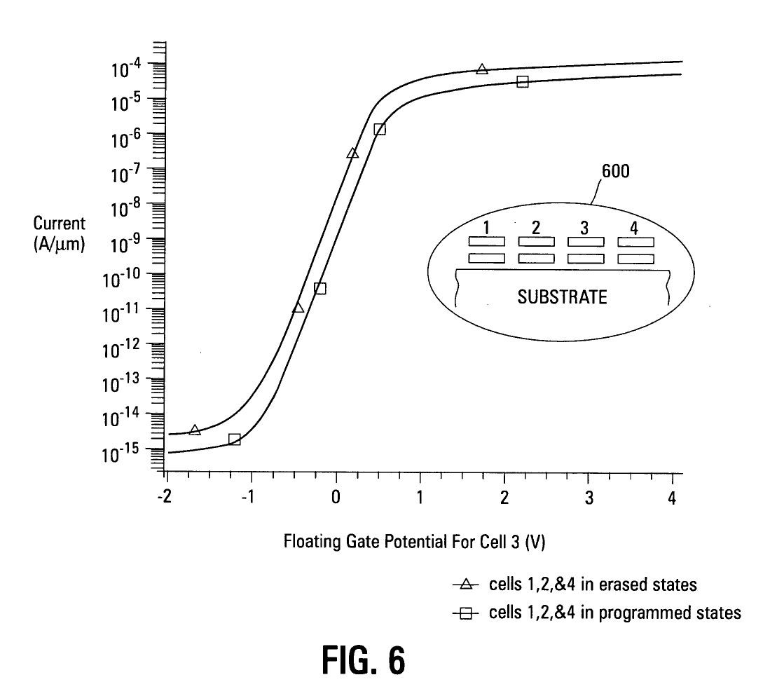

The cells of FIG. 2 can be numbered sequentially from left to right, starting at 1 (i.e., see insets 500 and 600 of FIGS. 5 and 6 respectively). Cell numbers 1, 2 and 4 are in erased states, or the floating gates are biased at ˜4V. As shown, the transistor can be effectively turned off (I_{d}<10⁻¹⁴ A/μm) when the gate voltage is lower than −0.5V (corresponding to a programmed state), and it can be turned on (I_{d}>10⁻⁶ A/μm) when the gate voltage is higher than 0.5V (corresponding to an erased state).

FIGS. 5 and 6 compare the on/off characteristics with cells in series (cell numbers 1, 2 and 4) in either programmed or erased states with low dose phosphorus (FIG. 5) or boron (FIG. 6) implants. As these figures show, the on/off characteristics are retained no matter whether cells 1, 2 and 4 are in erased or programmed state.

Therefore, simulation shows that gate-controlled fringing electric field can provide excellent on-off characteristics. Additionally, the present invention provides enough margin with regard to “programmed” (floating voltage around −1V, current less than 1 pA per bit line) and “erased state” (floating gate voltage around +1V, current more than 1 μA per bit line).

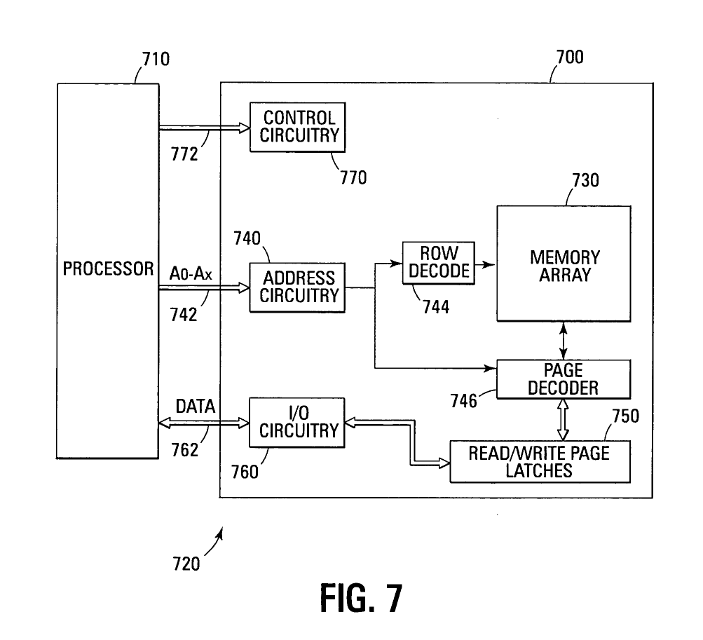

FIG. 7 illustrates a functional block diagram of a memory device 700 that can incorporate the non-volatile memory cells of the present invention. The memory device 700 is coupled to a processor 710. The processor 710 may be a microprocessor or some other type of controlling circuitry. The memory device 700 and the processor 710 form part of an electronic system 720. The memory device 700 has been simplified to focus on features of the memory that are helpful in understanding the present invention.

The memory device includes an array of memory cells 730 that can be comprised of the non-volatile memory cells previously illustrated. The memory array 730 is arranged in banks of rows and columns as illustrated in FIG. 3. The gates of each row of memory cells are coupled with a word line while the drain and source connections of the memory cells are coupled to bit lines.

An address buffer circuit 740 is provided to latch address signals provided on address input connections A0-Ax 742. Address signals are received and decoded by a row decoder 744 and a page decoder 746 to access the memory array 730. It will be appreciated by those skilled in the art, with the benefit of the present description, that the number of address input connections depends on the density and architecture of the memory array 730. That is, the number of addresses increases with both increased memory cell counts and increased bank and block counts.

The memory device 700 reads data in the memory array 730 by sensing voltage or current changes in the memory array columns using read/write page latch circuitry 750. This circuitry 750, in one embodiment, is coupled to read and latch a page of data from the memory array 730 and includes the sense amplifiers of the memory device 700. Data input and output buffer circuitry 760 is included for bi-directional data communication over a plurality of data connections 762 with the controller 710.

Control circuitry 770 decodes signals provided on control connections 772 from the processor 710. These signals are used to control the operations on the memory array 730, including data read, data write (program), and erase operations. The control circuitry 770 may be a state machine, a sequencer, or some other type of controller.

The memory device illustrated in FIG. 7 has been simplified to facilitate a basic understanding of the features of the memory. A more detailed understanding of internal circuitry and functions of memories are known to those skilled in the art.

### CONCLUSION

The embodiments of the present invention provide the ability to fabricate denser memory devices due to the lack of diffusion areas between the cells of a series string. The fabrication is also made easier since the step for implanting the diffusion areas is no longer required.

Although specific embodiments have been illustrated and described herein, it will be appreciated by those of ordinary skill in the art that any arrangement that is calculated to achieve the same purpose may be substituted for the specific embodiments shown. Many adaptations of the invention will be apparent to those of ordinary skill in the art. Accordingly, this application is intended to cover any adaptations or variations of the invention. It is manifestly intended that this invention be limited only by the following claims and equivalents thereof.

What is claimed is:

1. A memory device comprising:
a substrate; and
a plurality of memory cell stacks formed over the substrate, each memory cell stack coupled to adjacent memory cell stacks without diffusion regions.

2. The device of claim 1 wherein the adjacent memory cell stacks are coupled only through an electric field generated by each stack.

3. The device of claim 1 wherein the memory device is a NAND flash memory.

4. The device of claim 1 wherein each of the plurality of memory cell stacks is comprised of a floating gate and a control gate.

5. The device of claim 2 wherein the electric field is generated by a floating gate of each stack.

6. The device of claim 1 wherein the substrate is comprised of a p-type silicon.

7. The device of claim 4 wherein the floating gate and the control gate are comprised of silicon.

8. The device of claim 1 wherein the memory cell stacks are arranged in a memory array of rows and columns.

9. A NAND flash memory device comprising:
a substrate with an implanted n-layer; and
a plurality of series coupled memory cell stacks formed over the n-layer, each memory cell stack coupled to adjacent memory cell stacks without diffusion regions.

10. The device of claim 9 and further including a plurality of select transistors that enable predetermined subsets of the plurality of series coupled memory cell stacks.

11. The device of claim 10 wherein each select transistor is coupled to an adjacent memory cell stack through a diffusion region in the substrate.

12. The device of claim 10 wherein each select transistor is coupled to an adjacent memory cell stack only through an electric field generated by the adjacent memory cell stack and an electric field generated by the select transistor.

13. The device of claim 9 wherein each of the memory cell stacks comprises:
a tunnel dielectric layer formed over the n-layer;
a floating gate formed over the tunnel dielectric layer;
a gate dielectric layer formed over the floating gate layer; and
a control gate formed over the gate dielectric layer.

14. The device of claim 13 wherein the tunnel dielectric layer is comprised of an oxide.

15. The device of claim 13 wherein the tunnel dielectric layer is comprised of a material having a dielectric constant greater than silicon dioxide.

16. A NAND flash memory device comprising:
a memory controller for controlling memory operations;
a memory array, coupled to the controller, the memory array comprising:
a substrate; and
a plurality of memory cells formed over the substrate, each memory cell coupled to adjacent memory cells only through interaction of an electric field generated by each cell such that the plurality of memory cells are coupled serially in columns, each column of serially coupled memory cells grouped into a plurality of subsets of memory cells with a first select gate transistor on one end of each subset and a second select gate transistor on the other end of each subset.

17. The device of claim 16 wherein the first select gate transistor is a select gate drain transistor that couples the subset of memory cells to a bit line of the memory array and the second select gate transistor is a select gate source transistor that couples the subset of memory cells to a source line of the memory array.

18. The device of claim 16 wherein each memory cell in the memory array is coupled by a word line to adjacent memory cells in rows.

19. The device of claim 16 and further including diffusion regions between each.

20. The device of claim 16 wherein each of the plurality of memory cells is separated by a distance of less than 90 nm from adjacent memory cells.

21. An electronic system comprising:
a processor that generates memory signals; and
a memory device, coupled to the processor, that operates in response to the control signals, the device comprising:
a memory controller for controlling memory operations;
a memory array, coupled to the controller, the memory array comprising:
a substrate; and
a plurality of memory cells formed over the substrate, each memory cell coupled to adjacent memory cells without diffusion regions such that the plurality of memory cells are coupled serially in columns, each column of serially coupled memory cells grouped into a plurality of subsets of memory cells with a first select gate transistor on one end of each subset and a second select gate transistor on the other end of each subset.

22. The system of claim 21 wherein the memory controller is a state machine.

23. The system of claim 21 wherein each of the plurality of memory cells is comprised of a floating-gate with surrounding dielectric layers that together comprise an oxide-nitride-oxide film.

24. A method for programming a flash memory device comprising a memory array arranged in rows coupled by word lines and columns coupled by bit lines, the memory array comprising a plurality of memory cells formed over a substrate, the method comprising:
applying at least one programming pulse to a selected word line of the memory array; and
biasing unselected bit lines with an inhibit voltage such that a deep depletion area forms in the substrate under predetermined columns of memory cells.

25. The method of claim 24 wherein each memory cell is comprised of a tunnel oxide, a floating gate, a gate dielectric, and a control gate all formed over a channel region in the substrate, the deep depletion region suppressing electron tunneling from a channel region in the substrate.

26. The method of claim 24 wherein the inhibit voltage is V_{CC}.

27. The method of claim 24 and further including biasing selected bit lines at ground potential.

28. The method of claim 24 wherein the at least one programming pulse comprises a plurality of programming pulses that increment by a predetermined voltage.

29. A method for fabricating a flash memory device, the method comprising:
forming a plurality of memory cell stacks in a serial string over a substrate such that the stacks are not coupled by diffusion regions; and
forming a select gate transistor at each end of the serial string.

30. The method of claim 29 and further including forming a diffusion region between each select gate transistor and an adjacent memory cell stack.

31. The method of claim 29 wherein adjacent memory cell stacks of the serial string are formed sufficiently close such that an electric field generated by operation of a floating gate of each stack interacts with adjacent electric fields.
